(19) United States
(12) Patent Application Publication
(10) Pub. No.: US 2019/0043794 A1
(43) Pub. Date: Feb. 7, 2019

(54) ELECTRONICS PACKAGE INCLUDING INTEGRATED STRUCTURE WITH BACKSIDE FUNCTIONALITY AND METHOD OF MANUFACTURING THEREOF

(71) Applicant: General Electric Company, Schenectady, NY (US)

(72) Inventors: Christopher James Kapusta, Delanson, NY (US); Risto Ilkka Sakari Tuominen, Tokyo (JP); Kaustubh Ravindra Nagarkar, Clifton Park, NY (US); Raymond Albert Fillion, Niskayuna, NY (US)

(21) Appl. No.: 15/668,522

(22) Filed: Aug. 3, 2017

(51) Int. Cl. H01L 23/498; H01L 23/31; H01L 21/56; H01L 21/48

(52) U.S. Cl. CPC H01L 23/49827; H01L 23/3114; H01L 21/486; H01L 21/56; H01L 23/49811

(57) ABSTRACT

An electronics package includes a support substrate, an electrical component having an active surface coupled to a first surface of the support substrate, and an insulating structure coupled to the first surface of the support substrate and at least one side wall of the electrical component. A functional layer comprising at least one functional component is formed on at least one of a sloped side wall of the insulating structure and a backside surface of the electrical component. A first wiring layer is formed on a second surface of the support substrate. The first wiring layer is electrically coupled to the functional layer through at least one via in the support substrate.

### BACKGROUND OF THE INVENTION

Embodiments of the invention relate generally to semiconductor device packages or electronics packages and, more particularly, to an electronics package that includes an integrated interconnect structure formed from an insulating structure that at least partially surrounds an electrical component provided within the package. A miniaturized package topology is achieved by providing a functionality layer in the form of integrated, integral, and/or discrete components and/or electrical traces that are formed on or coupled to a portion of at least one sloped side wall of the insulating structure. In some embodiments, the functionality layer is at least partially formed on the backside surface of the electrical component, thereby allowing for “functionalization” of the back side of the electrical component.

State of the art electronics packaging covers a wide range of methods, structures, and approaches from wire bond modules to flip chip modules and to embedded chip modules. Wire bonded modules are a mature packaging approach that is low cost but has limited electrical performance. These modules use wires bonded to chip pads to connect the top I/O pads of power devices to an interconnect structure such as a metal-insulator-metal substrate such as ceramic, Aluminum Nitride (AlN), or Silicon Carbide (SiC) substrate with patterned metal on top and bottom. Wire bonds have inherently high inductance, generally high series resistance, current crowning on the bond pads, and microcracking within the semiconductor devices near bonding sites. An exemplary construction of a prior art wire bond electronics package 10 is illustrated in FIG. 1 with two power semiconductor devices 12 mounted onto a leadframe 14 using component attach material 16. Portions of the leadframe 14 extend beyond the molding resin 26 forming terminals 18. Wire bonds 20 connect die pads 22 located on the active surface 24 of semiconductor devices 12 to selected areas on the leadframe 14. Molding resin 26 encapsulates semiconductor devices 12, wire bonds 20, and exposed portions of leadframe 14. PowerRibbon® Bonding (K&S) is a modified version of power module wire bonding that replaces Al wire bonds with Al ribbons that use thermos-compression to bond to the chip pads. Beneficially, PowerRibbon© Bonding has lower resistance and therefore is targeted for higher current modules. However, PowerRibbon© Bonding has high inductance and can cause substrate microcracking.

Prior art flip chip modules experience reduced semiconductor substrate damage as compared to wire bond packages through the use of solder bumps, which have larger current carrying cross-sections than wire bonds. A general construction of a prior art flip chip electronic package 28 is illustrated in FIG. 2 with two semiconductor devices 12 attached to a top side metal layer 30 of substrate 32 by means of flip chip solder bumps 34. Thermal cooling is achieved with thermal connections 36 formed on the back side 38 of semiconductor devices 12. Molding resin 26 encapsulates the semiconductor devices 12, with portions of the top side metal layer 30 extending beyond the molding resin 26 forming terminals 18. While flip chip modules such as that illustrated in FIG. 2 provide some advantages over wire bond technology, the flip chip solder bumps have poor electrical conductivity, are susceptible to solder fatigue, are susceptible to electro-migration and provide a very poor thermal cooling pathway.

Prior art embedded device modules, such as the embedded device module 40 illustrated in FIG. 3 fabricated using General Electric Company's power overlay (POL) technology, address many of the limitations of wire bond and flip chip packages by eliminating wire bonds and solder bumps and replacing them with direct metallization contacts. In the embedded device module 40, semiconductor devices 12 are mounted onto a dielectric film 42. A post connector 44 is also attached to the dielectric film 42 to provide a top-to-bottom electrical connection for the module 40. Microvias 46 are formed through the dielectric film 42 to the input/output (I/O) contact pads 22 of semiconductor devices 12 and to the post connector 44. A metallization layer 48 is applied to the outer surface of the dielectric film 42, the microvias 46 and the exposed pads 22 to form an electrical connection to the semiconductor devices 12. The dielectric film 42 with attached semiconductor devices 12 and post connector 44 is bonded to a power substrate 32 using an electrically conductive component attach material 50 such as solder. The gaps between semiconductor devices 12 and post connector 44 are filled with a molding resin 26. The embedded device module 40 has reduced parasitics (e.g., resistance, capacitance, and inductance) and a superior thermal performance as compared to wire bond modules or flip chip modules.

Despite the advantages of an embedded device module construction, POL technology is more complex, less mature, and higher cost than wire bond and flip chip approaches. Electrical connections within the module 40 are typically formed by either forming through holes in module 40 using laser drilling and hole metallization or by forming a via to an inserted I/O structure or frame adjacent to the device that provide vertical connections. These approaches increase the complexity and cost of the module and can increase the module footprint.

In any of the above-described prior art packaging topologies, one or more separate discrete devices may be mounted alongside the semiconductor device(s) 12. Such separate and discrete devices may include various types of sensors, passive circuit elements, and active circuit elements. While incorporating these discrete devices adds functionally to the overall package, they increase package volume and pose a significant limitation to further miniaturization while maintaining or increasing performance.

Accordingly, it would be desirable to provide a new electronics packaging technology that permits construction of a highly miniaturized electronics package that includes backside functionality in the form of one or more discrete components, integral components, micro-electrical-mechanical systems (MEMS) components, antenna elements, added input/output (I/O) routing, thermal dissipation structures, “sensing” elements and/or shielding elements for the embedded electrical component.

### BRIEF DESCRIPTION OF THE INVENTION

In accordance with one aspect of the invention, an electronics package includes a support substrate, an electrical component having an active surface coupled to a first surface of the support substrate, and an insulating structure coupled to the first surface of the support substrate and at least one sidewall of the electrical component. A functional layer comprising at least one functional component is formed on at least one of a sloped sidewall of the insulating structure and a backside surface of the electrical component. A first wiring layer is formed on a second surface of the support substrate. The first wiring layer is electrically coupled to the functional layer through at least one via in the support substrate.

In accordance with another aspect of the invention, an electronics package includes a first support substrate and an electrical component having an active surface coupled to a first surface of the first support substrate, the active surface comprising at least one contact pad. An insulating structure with at least one sloped side wall is formed adjacent the electrical component and coupled to the first support substrate. The electronics package also includes a functional layer having at least one component formed on at least one of a backside surface of the electrical component and the at least one sloped sidewall of the insulating structure and at least connection line formed on the at least one sloped side wall of the insulating structure and electrically coupled to the at least one component. A first conductive layer extends through the first support substrate to couple with the at least one connection line.

In accordance with another aspect of the invention, a method of forming an electronics package includes bonding an active surface of an electronic component to a first surface of a support substrate, encapsulating at least a portion of the electronic component in a resin material, and forming a functional layer on at least one of a surface of the resin material and a backside surface of the electronic component, the functional layer comprising at least one functional component. The method also includes forming vias through the support substrate and forming a wiring layer on a second surface of the support substrate and into the vias to electrically connect to the functional layer.

These and other advantages and features will be more readily understood from the following detailed description of preferred embodiments of the invention that is provided in connection with the accompanying drawings.

### BRIEF DESCRIPTION OF THE DRAWINGS

The drawings illustrate embodiments presently contemplated for carrying out the invention.

In the drawings:

FIG. 1 is a schematic cross-sectional view of an exemplary prior art wire bond electronics package.

FIG. 2 is a schematic cross-sectional view of an exemplary prior art flip chip electronics package.

FIG. 3 is a schematic cross-sectional view of an exemplary prior art embedded chip electronics package.

FIG. 4 a schematic cross-sectional view of an electronics package, according to an embodiment of the invention.

FIG. 5 is a topside view of the electronics package of FIG. 4, with the insulating material omitted.

FIGS. 6-15 are schematic cross-sectional side views of the electronics package of FIG. 4 during various stages of a manufacturing/build-up process, according to an embodiment of the invention.

FIGS. 16 and 17 are schematic top views of the electronics package of FIG. 4 during select stages of the manufacturing/build-up process illustrated in FIGS. 6-15.

FIGS. 18-20 are schematic cross-sectional side views of the electronics package of FIG. 4 during various stages of a manufacturing/build-up process, according to an alternative embodiment of the invention.

FIG. 21 is a schematic cross-sectional view of an electronics package including an embedded functional layer, according to one embodiment of the invention.

FIG. 22 is a topside view of the electronics package of FIG. 21, with the insulating material and optional core structure, second insulating substrate, and top wiring layer omitted.

FIGS. 23-26 are schematic cross-sectional side views of the electronics package of FIG. 21 during various stages of a manufacturing/build-up process, according to an embodiment of the invention.

FIG. 27 is a schematic cross-sectional view of an electronics package including an embedded functional layer, according to another embodiment of the invention.

FIG. 28 is a schematic cross-sectional view of an electronics package including a multi-layer sloped surface, according to one embodiment of the invention.

FIG. 29 is a schematic cross-sectional view of an electronics package including an embedded functional layer, according to yet another embodiment of the invention.

FIG. 30 is a topside view of the electronics package of FIG. 29, with the insulating material and optional core structure, second insulating substrate, and top wiring layer omitted.

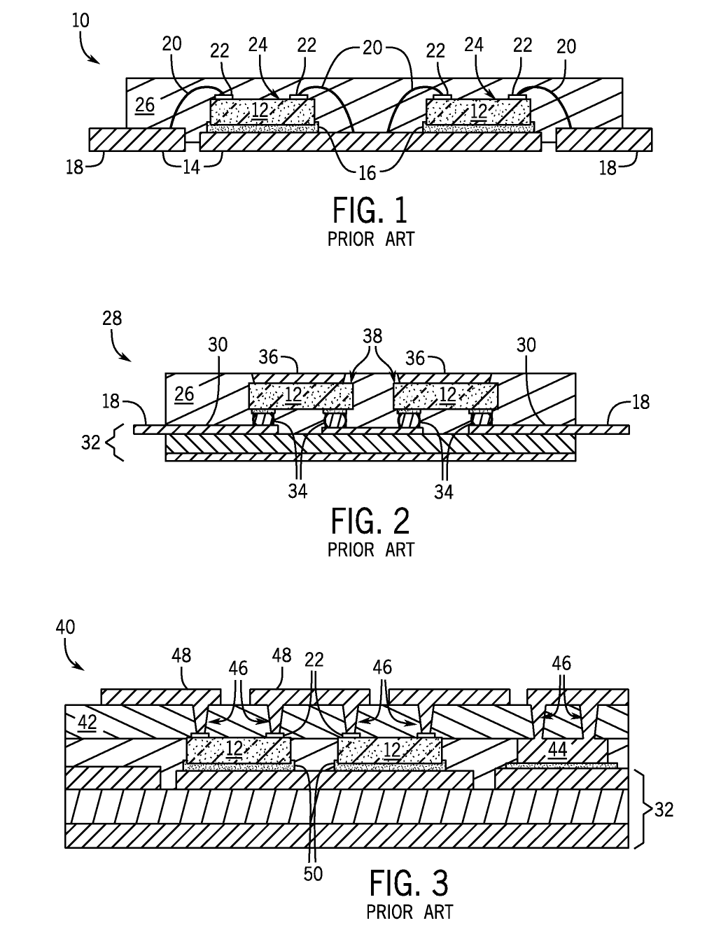

### DETAILED DESCRIPTION

Embodiments of the present invention provide for an electronics package or module that incorporates back side functionality to an embedded electrical component in a manner that facilitates miniaturization of the overall electronics package and at the same time adds functionality to the “un-used” space on the backside of an embedded component. As described in detail below, this back side functionality is achieved by incorporating a localized insulating structure that at least partially surrounds the electrical component within the electronics package. The insulating structure is provided with one or more sloped side walls that provide increased surface area on which a functional layer is formed. This functional layer provides back side functionality in the form of one or more integral or discrete components (e.g., a sensor, passive component, antenna, or identification tag), added input/output (I/O) routing, and/or thermal dissipation. Components incorporated within the functional layer may also provide a security feature in the form of anti-tamper and/or anti-counterfeit functionality. The resulting electronics package can be surface mounted onto a substrate or placed within a multi-component module for complex circuits.

As used herein, the term “semiconductor device” refers to a semiconductor component, device, die or chip that perform specific functions such as a power transistor, power diode, analog amplifier, RF element, as non-limiting examples. Typical semiconductor devices include input/output (I/O) interconnections, referred to herein as contacts or contact pads, which are used to connect the semiconductor device to external circuitry and are electrically coupled to internal elements within the semiconductor device. The semiconductor devices described herein may be power semiconductor devices used as electrically controllable switches or rectifiers in power electronic circuits, such as switched mode power supplies, for example. Non-limiting examples of power semiconductor devices include insulated gate bipolar transistors (IGBTs), metal oxide semiconductor field effect transistors (MOSFETs), bipolar junction transistors (BJTs), integrated gate-commutated thyristors (IGCTs), gate turn-off (GTO) thyristors, Silicon Controlled Rectifiers (SCRs), diodes or other devices or combinations of devices including materials such as Silicon (Si), Silicon Carbide (SiC), Gallium Nitride (GaN), and Gallium Arsenide (GaAs). Semiconductor devices may also be digital logic devices, such as a microprocessor, microcontroller, memory device, video processor, or an Application Specific Integrated Circuit (ASIC), as non-limiting examples.

While the various embodiments of an electronics package referenced below are shown and described as including a particular arrangement of a semiconductor device, interconnection wiring and electronic package terminals, it is understood that alternative arrangements and configurations could also be implemented and thus embodiments of the invention are not limited only to the specifically illustrated devices and arrangements thereof. That is, the electronics package embodiments described below should also be understood to encompass electronic packages that might include additional electronic components and/or one or more alternative device types of semiconductor devices including acoustic devices, microwave devices, millimeter devices, RF communication devices, and micro-mechanical (MEMS) devices. The electronics packages described herein may also include one or more resistors, capacitors, inductors, filters and similar devices and combinations thereof. As used herein the terms “electrical component” and “electronic component” may be understand to encompass any of the various types of semiconductor devices described above in addition to resistors, capacitors, inductors, filters and similar passive devices, and energy storage components.

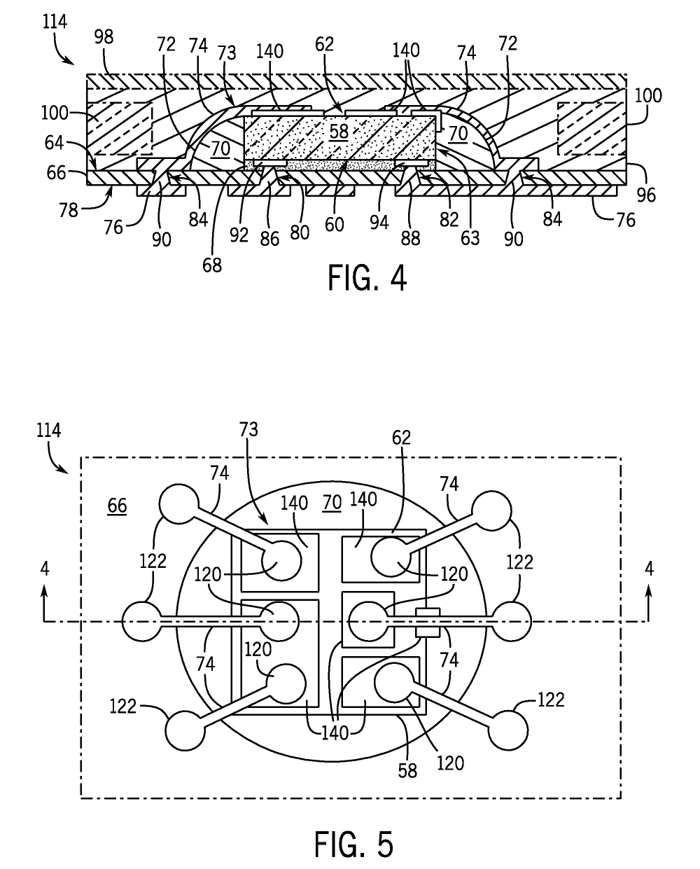

FIG. 4 illustrates an electronics package 114 including backside functionality, according to one embodiment of the invention. Electronics package 114 includes an electrical or electronic component such as a semiconductor device 58 having an active surface 60 and a back surface 62 or back side surface. In some embodiments, the back surface 62 of semiconductor device 58 may include one or more backside contact pads (not shown) in addition to a passivation layer (not shown) with openings to the backside contact pads. While electronics package 114 is illustrated as including one electrical component 58, it is contemplated that alternative embodiments may include multiple active electrical components as well as one or more passive devices such as, for example, capacitors, resistors, and/or inductors.

The active surface 60 of semiconductor device 58 is coupled to a first surface 64 of an insulating substrate 66 or support substrate using a component attach material 68. According to various embodiments, insulating substrate 66 may be provided in the form of an insulating film or dielectric substrate, such as for example a Kapton® laminate flex, although other suitable electrically insulating materials may also be employed, such as Ultem®, polytetrafluoroethylene (PTFE), or another polymer film, such as a liquid crystal polymer (LCP) or a polyimide substrate, as non-limiting examples. Component attach material 68 is an electrically insulating material that adheres to surrounding components of the electronics package 114 such as a polymeric material (e.g., epoxy, silicone, liquid crystal polymer, or a ceramic, silica, or metal filled polymer) or other organic material as non-limiting examples. In some embodiments, component attach material 68 is provided on insulating substrate 66 in either an uncured or partial cured (i.e., B-stage) form. Alternatively, component attach material 68 may be applied to semiconductor device 58 prior to placement on insulating substrate 66. In alternative embodiments, semiconductor device 58 may be affixed to insulating substrate 66 by way of an adhesive property of the insulating substrate 66 itself. In such an embodiment, component attach material 68 is omitted and insulating substrate 66 is provided in the form of a single dielectric layer having adhesive properties. Non-limiting examples of such an adhesive dielectric layer include a spin-on dielectric such as polyimide or polybenzoxzaole (PBO).

An insulating structure 70 with at least one tapered or sloped side surface or side wall 72 is coupled to the first surface 64 of insulating substrate 66. According to alternative embodiments, insulating structure 70 may be a cured photo-patternable resin material, a polymer such as, for example, an epoxy material, a pre-preg material, a composite dielectric material, or any other electrically insulating organic or inorganic material.

In the illustrated embodiment, a functional layer 73 is provided on the back surface 62 of semiconductor device 58 and, optionally, select portions of one or more side surfaces 63 of semiconductor device 58. Alternatively, all of functional layer 73 or select portions thereof may be formed on the outer surface or sloped side wall 72 of insulating structure 70, the back surface 62 of semiconductor device 58, and/or cover a portion of the first surface 64 of insulating substrate 66, as described in more detail with respect to other embodiments disclosed herein. According to various embodiments, functional layer 73 includes one or more integral, discrete, and/or integrated components 140, which are formed on or coupled to the back surface 62 of semiconductor device 58, one or more side surfaces 63 of semiconductor device 58, the sloped side wall 72 of insulating structure 70, and/or the first surface 64 of insulating substrate 66. Depending on their functionality, components 140 may be single or multi-layer structures and may be formed of a single material or multiple materials.

Components 140 may be provided in the form of discrete passive components such as resistors, capacitors, inductors, or combinations thereof, integral passive components such thin film resistors, capacitors or inductors, and/or integrated components such as for example, battery cells, transistors, thin-film type sensors, saw devices, or transducers including, but not limited to, components configured to monitor audio, motion, force, temperature, magnetic field, light, and other conditions. Components 140 may also be provided in the form of integral or integrated transistor elements, optical components, electromechanical or micro-electromechanical (MEMS) elements, antennas, identification elements including, for example, RFID tags incorporated for anti-counterfeiting purposes, or other types of discrete, integral, integrated or non-integrated circuit, active or non-active circuit element devices semiconductor or non-semiconductor, or any combinations of these different types of devices. As used herein, the terms “integral” and “integrated” refer to components that are fabricated directly on the structure to which they are attached as compared to a “discrete” component, which is separately manufactured and coupled to its respective attachment structure by way of an adhesive or other component attach material. In embodiments where components 140 are integral or integrated devices, it is contemplated that components 140 may have a thickness of approximately 1 μm, as one non-limiting example, making the components virtually invisible relative to the size of the semiconductor device 58. As a result, the incorporation of functional layer 73 does not change the overall size of the electronics package.

In the illustrated embodiment, multiple components 140 are formed on or coupled onto semiconductor device 58, with a number of integral or integrated components 140b formed on the back surface 62 of semiconductor device 58 and integral or integrated component 140b extending over the back surface 62 and onto side surface 63. Individual components 140 may be located entirely on either the back surface 62 or a side surface 63, or may be formed to span the transition between the two of the surfaces, such that a portion of a respective component 140 is located on one surface of semiconductor device 58 and another portion of the respective component 140 is located on another surface of semiconductor device 58. Alternative embodiments may include a single component or any number of multiple components arranged on the back surface 62 or side surface(s) 63 of semiconductor device 58. When located on back surface 62 or side surface 63, components 140 may be electrically and communicatively isolated from device 58 or coupled thereto through one or more contact pads (not shown) located on surfaces 62 and/or 63 of the semiconductor device 58.

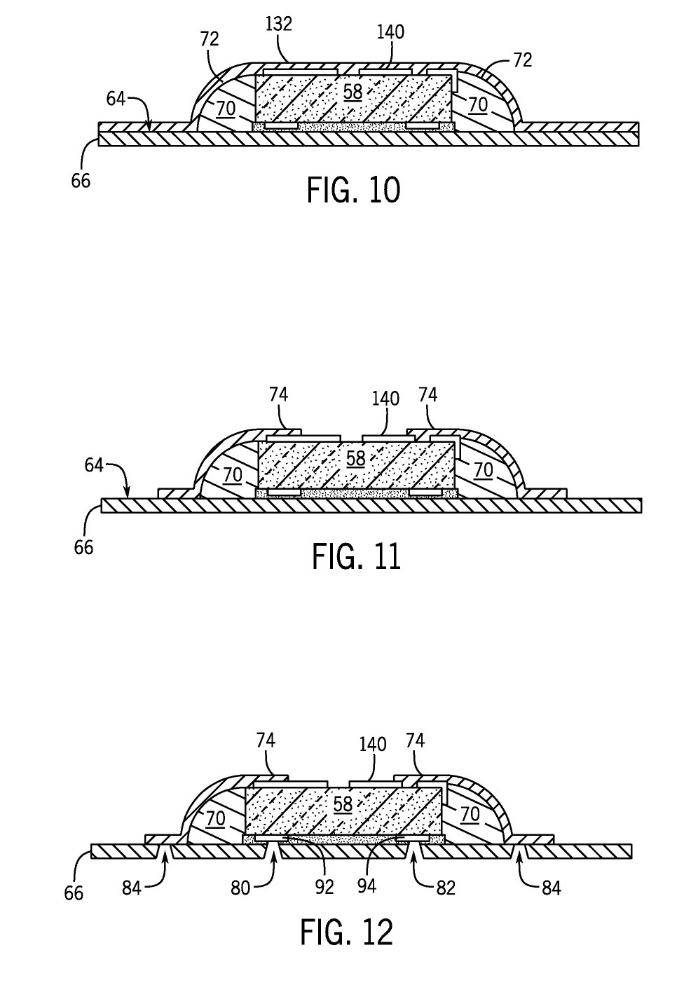

Functional layer 73 also includes at least one connection line 74 that forms a connection between select components 140 and wiring layer 76. Connection lines 74 may be formed on the back surface 62 of semiconductor device 58, the sloped side wall 72 of insulating structure 70, or first surface 64 of insulating substrate 66. Depending on the functionality of connected components 140, connection lines 74 may be electrical lines or communication lines and are formed from conductive materials such as aluminum, copper, gold, silver, nickel, or combinations thereof as non-limiting examples, or an electrically conductive polymer. Connection lines 74 may also be formed of a non-conductive material, including, without limitation, a material enabling optical sensing, communication, fiber-optic data transmission and receipt. Connection lines 74 also may be multi-layer, multi-purpose components formed of a combination of conductive and non-conductive materials, thereby enabling a combination of electrical coupling and at least one of sensing and communication. Connection lines 74 may also be provided to couple select components 140 to one another. While FIG. 10 illustrates a connection line 74 associated with each component 140, select components 140 may be electrically isolated from each other on the back surface 62 of semiconductor device 58 in an alternative embodiment.

A topside view of electronic package 114 is provided in FIG. 5, with insulating material 96, optional core structure 100, and insulating substrate 98 omitted for purposes of clarity to illustrate an exemplary configuration of functional layer 73. In the illustrated embodiment, functional layer 73 includes multiple electrical traces or connection lines 74 that each include a first terminal pad 120 and a second terminal pad 122. Each first terminal pad 120 is electrically coupled to a respective component 140 located on the back surface 62 of the semiconductor device 58. Respective second terminal pads 122 are located on the first surface 64 of the insulating substrate 66 and are electrically coupled to wiring layer 76 through penetrating contacts 90. Each of these lines 74 thus forms an electrical and/or communication connection between the wiring layer 76 and respective component(s) 140. The width and/or thickness of the lines 74 may be varied from trace to trace within the electronics package 114 depending on the current carrying requirements and particular function of the associated component 140, with wider and/or thicker lines 74 being formed to components 140 with higher current carrying requirements as appropriate.

Referring again to FIG. 4, a wiring layer 76 is disposed on a second surface 78 of insulating substrate 66 and into vias 80, 82, 84 formed through insulating substrate 66. While referred to herein as a wiring layer 76, it is contemplated that layer 76 may be formed using a combination of conductive and non-conductive materials and with a series of routing paths or traces that enable electrical coupling and sensing and/or communication to and from components 140. Penetrating contacts 86, 88, 90 are formed, which electrically couple the wiring layer 76 to contact pads 92, 94 located on the active surface 60 of semiconductor device 58 and to functional layer 73, respectively. Contact pads 92, 94 provide conductive routes (I/O connections) to internal contacts within semiconductor device 58. Contact pads 92, 94 may have a composition that includes a variety of electrically conductive materials such as aluminum, copper, gold, silver, nickel, or combinations thereof as non-limiting examples. While illustrated as structures that protrude outward from the active surface 60 of semiconductor device 58, contact pads 92, 94 may also be contact terminals located substantially flush or level with the active surface 60 of semiconductor device 58.

An electrically insulating material 96 overlays semiconductor device 58, insulating structure 70, functional layer 73, and exposed portions of the first surface 64 of insulating substrate 66. Insulating material 96 may encapsulate all of semiconductor device 58 or portions thereof, in alternative embodiments.

In some embodiments electronics package 114 also includes an optional second insulating substrate 98 (shown in phantom) provided atop the insulating material 96 and/or an optional support structure or a core structure 100 (shown in phantom) that provides additional dimensional stability to electronics package 114. Insulating substrate 98 may be formed from any of the same materials as insulating substrate 66. Core structure 100 may be a printed circuit board (PCB) core material, such as, for example, an epoxy material with a fiberglass mat, a pre-preg material, polyimide film/layer, a ceramic material, glass, aluminum, a composite dielectric material, or other similar/suitable organic material or inorganic material that provides mechanical robustness to electronics package 114. While not illustrated in FIG. 4, in embodiments where core structure 100 is a printed circuit board, it is contemplated that wiring layer 76 may extend through additional microvias in insulating material 96 and in insulating substrate 66 to electrically couple with contact locations on the bottom and/or top surfaces core structure 100. In such an embodiment, a bonding layer (not shown) would be incorporated to couple the insulating substrate 66 to core structure 100.

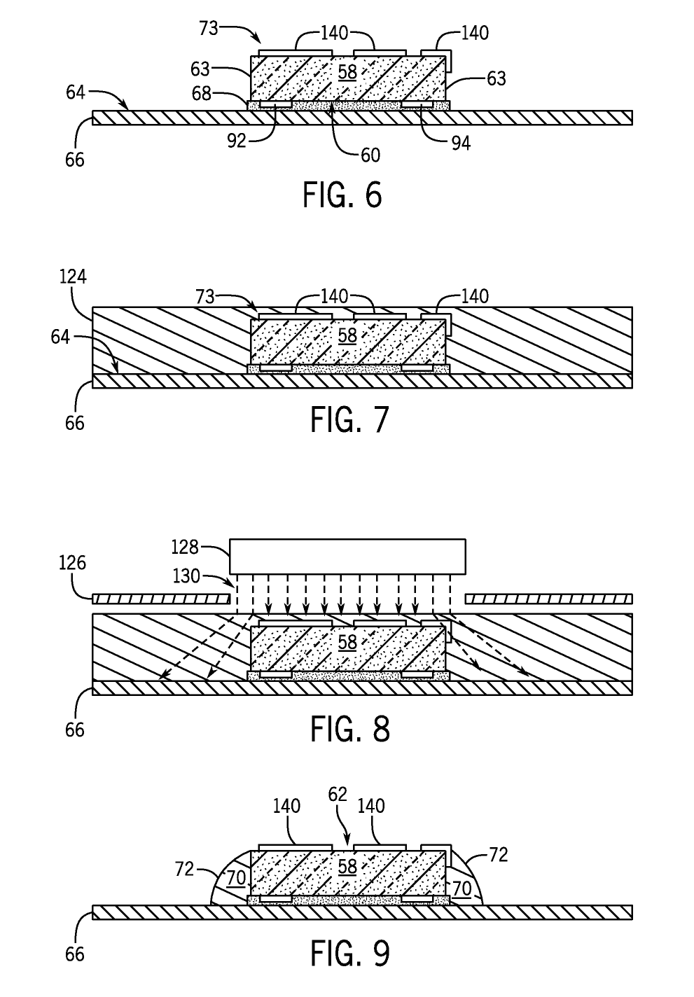

Referring now to FIGS. 6-15, a technique for manufacturing the electronics package electronics package 114 of FIGS. 4 and 5 is set forth, according to one embodiment of the invention, with each figure illustrating a cross-section of the electronics package 114 during the build-up process. While FIGS. 6-15 illustrate the manufacture of a single electronics package, one skilled in the art will recognize that multiple electronics packages could be manufactured in a similar manner at the panel level and then singulated into individual electronics packages as desired.

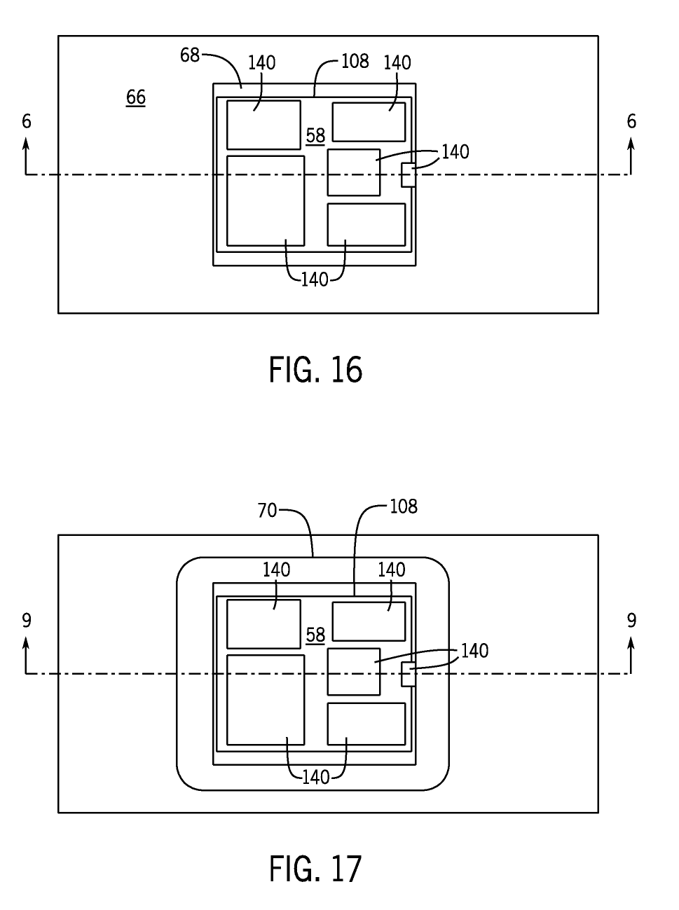

Referring first to FIG. 6, fabrication of electronics package 114 begins by applying component attach material 68 to the first surface 64 of insulating substrate 66. Component attach material 68 is applied to coat component attach locations, and in some embodiments extends outside the outer perimeter 108 of the semiconductor device 58, as shown in FIG. 16. In some embodiments, the component attach material 68 may be applied by stencil, screen printing, or using a direct dispense technique such as ink jetting, for example. Component attach material 68 may have a thickness in the range of 2 to 50 in one exemplary and non-limiting embodiment. In alternative embodiments, component attach material 68 may be applied to coat the entirety of exposed surfaces of insulating substrate 66, applied to semiconductor device 58 prior to positioning semiconductor device 58 on insulating substrate 66, be provided having a thickness outside the previously stated range, or omitted entirely in cases where insulating substrate 66 has adhesive properties.

Semiconductor device 58 is placed active surface 60 face down into the component attach material 68 using conventional pick and place equipment and methods. After being positioned, the semiconductor device 58 is bonded to insulating substrate 66 by fully curing component attach material 68 using heat, UV light, or microwave radiation, as examples. In one embodiment, a partial vacuum and/or above atmospheric pressure may be used to promote the removal of volatiles from the adhesive during cure if any are present.

All or portions of functional layer 73 may be formed on the backside surface 62 and/or sidewalls 63 of semiconductor device 58 either before or after semiconductor device 58 is affixed to insulating substrate 66, according to alternative embodiments. As one example, some or all of functional layer 73 are fabricated on the backside surface 63 of semiconductor device 58 at the wafer level prior to singulation. Once the semiconductor device 58 is singulated, additional portions of functional layer 73 may be formed on one or more sidewalls 63 of device 58 before device 58 is affixed to insulating substrate 66. Alternatively, all or portions of functional layer 73 are formed on backside surface 62 and/or sidewalls 63 after semiconductor device 58 is coupled to insulating substrate 66.

The individual components 140 of functional layer 73 may be formed by a combination of material systems (sensing elements, metallization, dielectrics, semiconducting films, etc.) and processes (deposition, etching, patterning, laser, additive manufacturing). In one embodiment, functional layer 73 is fabricated by forming components 140 and any associated connection lines 74 as a thin film on the backside 62 and/or side surfaces 63 of semiconductor device 58 using an additive process (e.g., three-dimensional (3D) printing, including laser printing), a deposition process, a patterning process, other known fabrication process, or a combination thereof. One or more different types of conductive and/or non-conductive materials may be applied to within different regions of the functional layer 73 and in different layers depending on the type of component 140 and associated connection lines 74 being formed. Alternatively, some or all of components 140 may be positioned on the back surface 62 and/or side surface(s) 63 of semiconductor device 58 using a pick and place machine and coupled to the respective surface with a component attach or joining material. Thereafter, any connection lines 74 may be formed to communicatively or electrically couple respective components 140 using any of the techniques described above. These connection lines 74 may either be formed at this stage of the manufacturing technique or after formation of insulating structure 70, as described in more detail below.

In a next step of the fabrication technique shown in FIG. 7, insulating structure 70 is formed by applying a layer of photo-patternable resin material 124 over the entire semiconductor device 58 and to coat the first surface 64 of insulating substrate 66 fully encapsulating semiconductor device 58. A photo-patterning mask 126 is placed over the top surface of the photo-patternable resin material 124 as shown in FIG. 8. The photo-patternable resin material 124 is then patterned by radiating a beam of unfocused light emitted by a light source 128 through one or more openings 130 in the mask 126. The width of the beam of light will expand as it extends into the photo-patternable resin material 124 and selectively cure regions of the photo-patternable resin material 124 below the opening 130. A solvent rinse is used thereafter to remove uncured photo-patternable resin material 124. Cured resin material is then removed from the back surface 62 of semiconductor device 58 and the backside contact pad(s) 116 provided thereon, leaving the cured insulating structure 70 illustrated in FIG. 9. As shown in the top view provided in FIG. 17, the insulating structure 70 surrounds the outer perimeter 108 of semiconductor device 58. In alternative embodiments, insulating structure 70 may be formed to only partially surround the outer perimeter 108 of semiconductor device 58. In yet another embodiment, the insulating structure 70 may be patterned by a direct write imaging system such as a laser. Alternatively, insulating structure 70 may be formed using a grey scale mask.

In alternative embodiments, insulating structure 70 is formed by applying an insulating resin to at least one of the edges of the outer perimeter 108 of semiconductor device 58. This insulating resin may be, for example, an organic underfill resin or epoxy with filler material such as, for example, ceramic or silica filler particles, to reduce its coefficient of thermal expansion. Deposition of the insulating resin can be accomplished using a direct dispense tool such as an ink jet printer, a spray system, a 3D printing technique, or a liquid dispense head, as non-limiting embodiments. Thereafter, the resin material is cured using heat, UV light, microwaves, or the like. Optionally, the insulating resin can be applied to form a layer of material coating the insulating substrate 66 and/or the backside surface 62 of semiconductor device 58 and selectively patterned to remove select portions of the applied insulating resin on the insulating substrate 66 and/or the backside surface 62 of semiconductor device 58 to yield the insulating structure 70 illustrated in FIG. 9. Alternatively, the insulating resin could be locally dispensed around the perimeter 108 of semiconductor device 58, without covering the entire surface of insulating substrate 66.

After forming insulating structure 70, some or all of connection lines 74 are formed by applying one or more layers of conductive and/or non-conductive materials 132 on the sloped side walls 72 of insulating structure 70, the back surface 62 of semiconductor device 58, and exposed regions of the first surface 64 of insulating substrate 66 as shown in FIG. 10. According to alternative embodiments, layer 132 includes a metal such as copper, aluminum, or other standard wiring metal, may contain a barrier metal such as titanium, and is deposited by one or more of sputtering, evaporation, electroless plating, electroplating, or other standard metal deposition processes. The conductive material 132 is then patterned to form connection lines 74. In one embodiment, the patterning step may be carried out using a semi-additive patterning technique wherein a first seed metal or barrier metal (e.g., titanium) is applied to the sloped side walls 72 of insulating structure 70 and the exposed regions of the first surface 64 of insulating substrate 66. A photo-resist (not shown) is applied to the seed metal and patterned, a layer of bulk metal (e.g., copper) is plated up atop the seed or barrier metal. The barrier layer can have a thickness of 0.01 to 1 micron and the bulk metal can have a thickness of 1 to 20 microns according to an exemplary, non-limiting embodiment. The photo-resist is removed and the exposed seed layer is removed by etching. The remaining seed metal and the plated up layer of metal form the connection lines 74 illustrated in FIG. 11. In alternative embodiments connection lines 74 may be formed from conductive or non-conductive materials and using other known patterning techniques such as, for example, fully subtractive patterning, semi-additive pattern plate-up, or additive plate-up. In yet other embodiments connection lines 74 could also be printed with conductive pastes, or laser activated and then selectively plated.

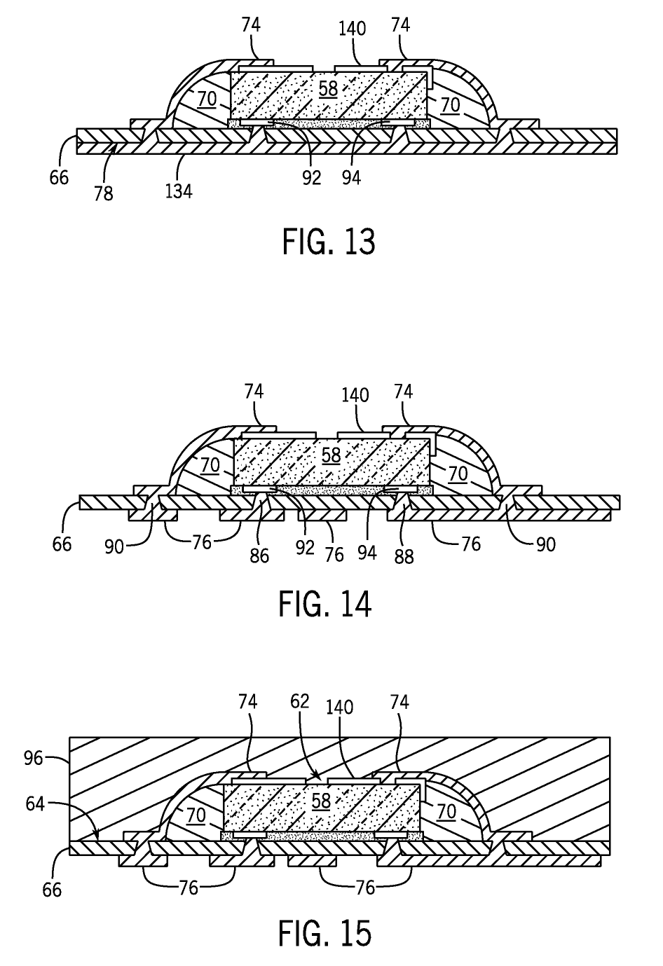

Referring next to FIG. 12, vias 80, 82, 84 are formed through insulating substrate 66 to select areas of functional layer 73 and to contact pads 92, 94 of semiconductor device 58 by known standard microvia processes, including laser drilling or ablation, mechanical drilling, photo-definition, plasma etch, or chemical etch, and the like. After the vias 80, 82, 84 are formed, a second layer of conductive material 134 is deposited onto the second surface 78 of insulating substrate 66 as shown in FIG. 13. The layer of conductive material 134 is patterned thereafter to form wiring layer 76 as shown in FIG. 14. Deposition and patterning may be carried out in a similar manner as described above for the layer of conductive material 132 that is used to form functional layer 73. This second layer of conductive material 134 extends into vias 80, 82, 84, thereby forming penetrating contacts 86, 88, 90.

The manufacturing process continues in FIG. 15 by applying insulating material 96 over the back surface 62 of semiconductor device 58, functional layer 73, exposed portions of insulating structure 70, and exposed portions of insulating substrate 66 to form a body for the electronics package 114. According to alternative and non-limiting embodiments, insulating material 96 may be applied using a pour molding, injection molding, or compression molding process. In embodiments that include optional core structure 100, the core structure 100 may be adhesively coupled to the first surface 64 of the insulating substrate 66 prior to applying the insulating material 96 in a similar manner as later described with respect to FIG. 24.

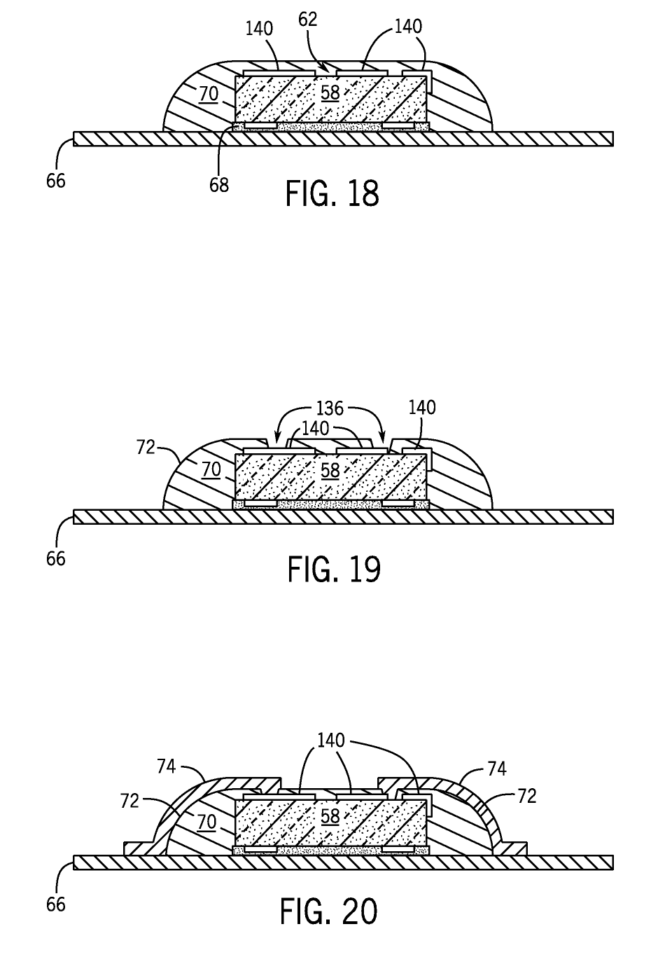

FIGS. 18-20 illustrates steps of a modified manufacturing process that may be used in embodiments where electronics package 114 includes semiconductor device(s) 58 that do not have a back surface passivation layer. In such an embodiment, manufacture of electronics package 114 would begin in a similar manner as described for FIGS. 6 and 7 by coupling semiconductor device(s) 58 to insulating substrate 66 and applying photo-patternable resin material 124. Once cured, a portion of the insulating structure 70 would be retained to cover the backside surface 62 of semiconductor device 58, as shown in FIG. 18.

Referring to FIG. 19, one or more microvias 136 are formed through the insulating structure 70 to one or more of components 140 using similar techniques as described above for vias 80, 82, 84. Connection lines 74, shown in FIG. 20, are then formed by depositing and patterning one or more layers of conductive and/or non-conductive material on the sloped side wall 72 of insulating structure 70 and into the one or more microvias 136 using any of the previously described techniques, thereby electrically connecting components 140 to respective connection lines 74. Fabrication of the electronics package would then continue in accordance with the steps illustrated in FIGS. 12-15.

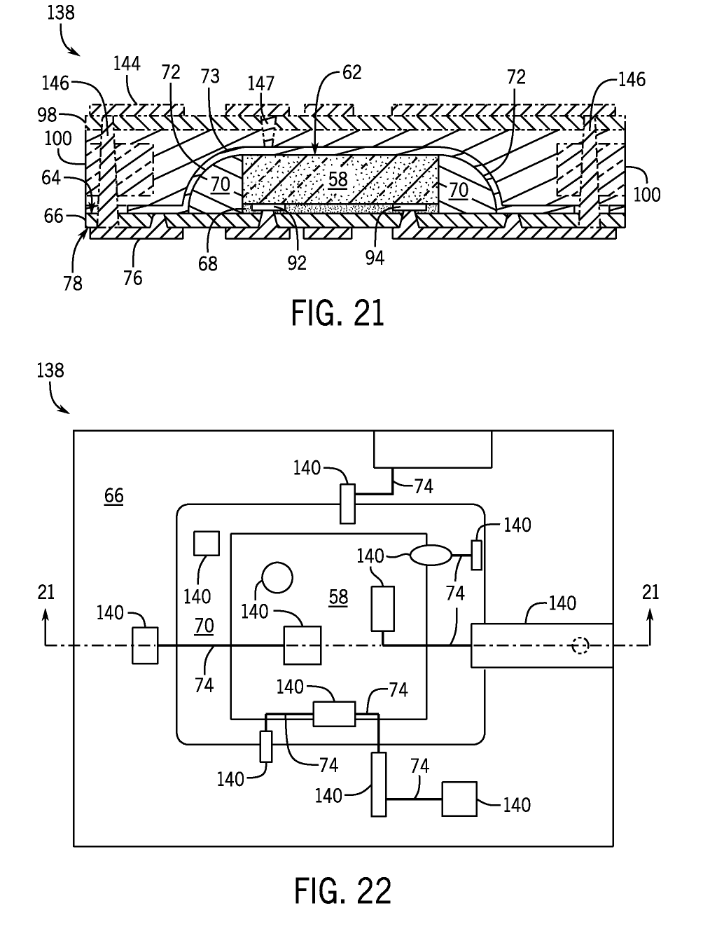

Referring now to FIGS. 21 and 22, an electronics package 138 is illustrated according to another embodiment. Electronics package 138 includes a number of components similar to those included in electronics package 114 (FIG. 4), which are referred to with common part numbers as appropriate. Electronics package 138 differs from electronics package 114 in that the components 140 of functional layer 73 and any associated electrical connection lines 74 may be formed on portions of the sloped side wall 72 of insulating structure 70, and/or on exposed portions of the first surface 64 of insulating substrate 66, and/or on the backside surface 62 of semiconductor device 58. According to alternative embodiments, components 140 may be discrete, integral, or integrated components (or a mixture thereof), and may be provided in combination with one or more communication lines or electrical connection lines 74, an exemplary configuration of which is illustrated in FIG. 22. As shown, components 140 may be electrically isolated from each other and any connection lines 74 or may be connected together via one or more connection lines 74.

In one embodiment, electronics package 138 includes an optional wiring layer 144 (shown in phantom in FIG. 21) that is formed on optional insulating substrate 98 (shown in phantom). Wiring layer 144 may be coupled to wiring layer 76 by way of one or more optional metalized through connections 146 (shown in phantom) that extend through insulating material 96 and core structure 100 or directly through insulating material 96 if core structure 100 is omitted. Optionally, one or more penetrating contacts 147 may be formed to electrically couple wiring layer 144 to functionality layer 73. Through connections 146 and penetrating contacts 147 can be formed by first forming a hole through the electronics package 138 by any standard board through hole process such as for example mechanical drilling, laser drilling, plasma etch or the like. The hole can be filled with conductive material such as for example copper by a combination of sputtering, CVD, electroless plating, electro-plating for example. It is contemplated that a third wiring layer and through connections may be incorporated within electronics package 114 (FIG. 4) in a similar manner. Similar to wiring layer 76, optional wiring layer 144 may be formed from a conductive material, non-conductive material, or combinations thereof to create routing patterns for transmission of electrical and/or communication signals.

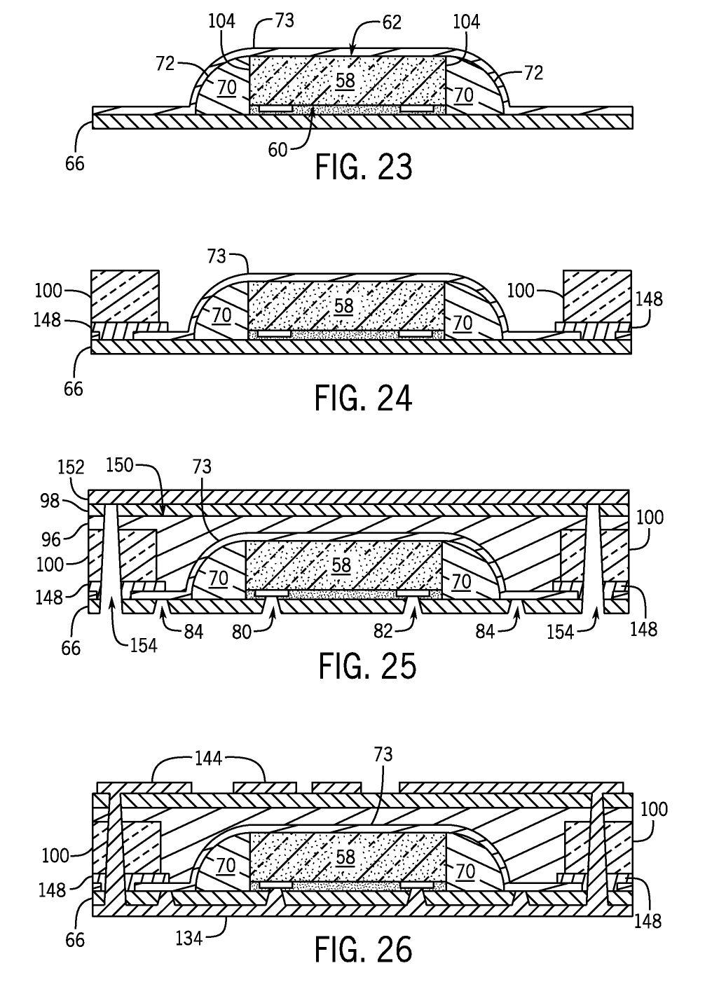

Manufacture of electronics package 138 begins in a similar manner as described with respect to FIGS. 6-12 by coupling semiconductor device 58 to insulating substrate 66 and forming insulating structure 70 around a least a portion of one or more of the side walls 104 of semiconductor device 58. The manufacturing process for package 138 differs from that of electronics package 114 in that semiconductor device 58 does not include a component-specific functional layer 73 that is formed on device 58 either before component attach or before application of photo-definable layer 124. As a result, functional layer 73 is formed on select portions of the back surface 62 of semiconductor device 58 and/or along the sloped side wall 72 of insulating structure 70 and onto at least a portion of the exposed first surface 64 of insulating substrate 66, as shown in FIG. 23. Functional layer 73 is fabricated by forming devices 140 and any associated connection lines 74 as a thin film atop semiconductor device 58 and/or insulating structure 70 and/or first surface 64 of insulating substrate 66 using any combination of material systems and processes described above with respect to electronics package 114. Alternatively, some or all of devices 140 may be positioned on the back surface 62 of semiconductor device 58 and/or along the sloped side wall 72 of insulating structure 70 and/or first surface 64 of insulating substrate 66 using a pick and place machine and coupled to the respective surface with an adhesive or joining material. Thereafter, any connection lines 74 may be formed to communicatively or electrically couple respective devices 140 using any of the techniques described above.

In embodiments that include core structure 100, a joining material 148 is applied exposed portions of insulating substrate 66 and portions of functional layer 73 and used to couple them to core structure 100, as shown in FIG. 24. The manufacturing process continues in FIG. 25 by applying insulating material 96 to surround core structure 100, functional layer 73 and any exposed portions of insulating structure 70 using any of the techniques previously described with respect to FIG. 15.

After the insulating material 96 is cured, second insulating substrate 98 is coupled to the top surface 150 of insulating material 96 as shown in FIG. 25. Thereafter, a third layer of conductive material 152 is deposited on the second insulating substrate 98. Vias 80, 82, 84 and any through holes 154 are formed. The third layer of conductive material 152 is patterned to form the wiring layer 144 shown in FIG. 26, and the second layer of conductive material is deposited onto the second surface 78 of insulating substrate 66 and into vias 80, 82, 84 and any through holes 154. The second layer of conductive material 152 is also patterned to yield wiring layer 76.

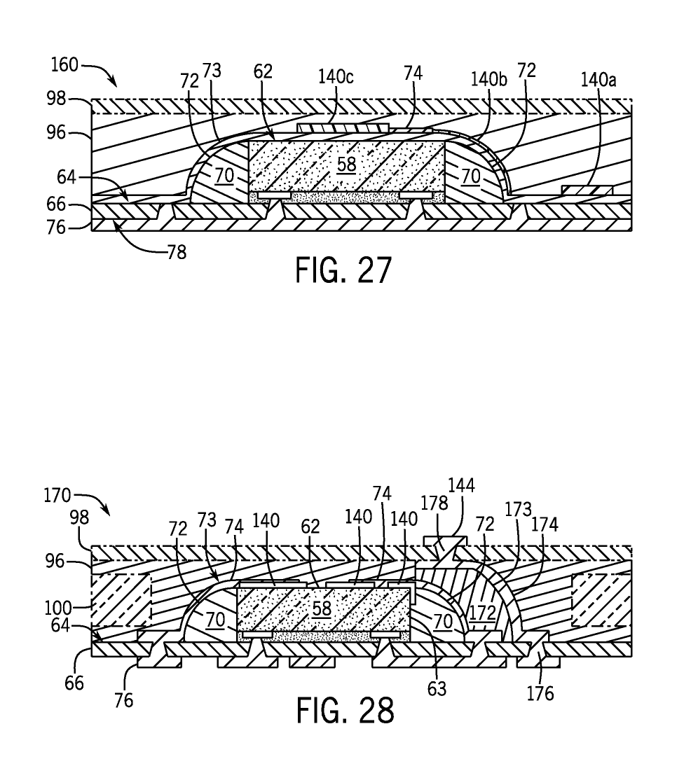

Referring now to FIG. 27, an electronics package 160 is illustrated according to yet another embodiment. Electronics package 160 includes a number of components similar to those included in electronics package 138 (FIG. 21), which are referred to with common part numbers as appropriate. Similar to the previously described embodiment, the functional layer 73 is formed on the sloped side wall 72 of insulating structure 70 and extends across the back surface 62 of semiconductor device 58, down the sloped side wall(s) 72 of insulating structure 70, and onto exposed portions of the first surface 64 of insulating substrate 66.

An exemplary configuration of components 140 and connection lines 74 of functional layer 73 are illustrated in FIG. 27, with multiple components 140 being formed or coupled onto various portions of the functional layer 73 with integrated component 140c coupled on the back surface 62 of semiconductor device 58, integral component 140b formed on the sloped side wall 72 of insulating structure 70, and discrete component 140a coupled to the first surface 64 of insulating substrate 66. Individual components 140 may be located entirely on either the back surface 62 or sloped side wall 72 or the first surface 64 of insulating substrate 66, or may be formed to span the transition between the two of the surfaces, such that a portion of a respective component 140 is located on semiconductor device 58 and another portion of the respective component 140 is located on insulating structure 70. Alternative embodiments may include a single component or any number of multiple components and/or arranged on second surface 78 of insulating substrate 66 and/or on the outer surface of insulating substrate 98. Components 140 may be isolated on insulating structure 70 and/or back surface 62 of semiconductor device 58 and/or first surface 64 of insulating substrate 66. Alternatively, components 140 may be coupled to one another through at least one connection line 74 formed on the back surface 62 of semiconductor device 58, the sloped side wall 72 of insulating structure 70, or first surface 64 of insulating substrate 66. Depending on the functionality of connected components 140, connection lines 74 may be electrical lines or communication lines and are formed from conductive or non-conductive materials.

Yet another embodiment of an electronics package 170 incorporating a semiconductor device 58 and backside functionality is illustrated in FIG. 28. Electronics package 170 includes a number of common structures as electronics package 114 (FIG. 4) and electronics package 138 (FIG. 21), which are referred to with common part numbers as appropriate. In the illustrated embodiment, functional layer 73 is formed in a similar manner as described with respect to FIG. 4, with components 140 formed on the back surface 62 and (optionally) side surface(s) 63 of semiconductor device 58 and connection lines 74 formed on the sloped side walls 72 and top surface 64 of insulating structure 70 and insulating substrate 66, respectively. It is also contemplated that some or all of components 140 may be formed on or coupled to sloped side walls 72 of insulating structure and (optionally) the top surface 64 of insulating substrate 66 in a similar manner as described with respect to electronics package 138.

In addition to structures common to electronics packages 114 and 138, electronics package 170 includes a second insulating structure 172 that is formed atop or directly adjacent at least a portion of the insulating structure 70. The second insulating structure 172 may be formed using any of the same materials and techniques described herein with respect to insulating structure 70. Second insulating structure 172 may be formed at one or more discrete locations atop insulating structure 70, or may completely surround insulating structure 70 in alternative embodiments.

A wiring layer 174 is formed on the sloped surface 173 of second insulating structure 172 using any of the same materials and techniques as described with respect to wiring layer 76. Wiring layer 174 is electrically coupled to wiring layer 76 by way of a penetrating contact 176 that extends through insulating substrate 66. Another penetrating contact 178 extends through second insulating substrate 98 to similarly electrically couple wiring layer 174 to wiring layer 144. In the illustrated embodiment, the second insulating structure 172 is formed having a height larger than that of insulating structure 70 to facilitate a connection between wiring layers 76 and 144. In an alternative embodiment, second insulating structure 172 may be formed having a height less than that of insulating structure 70, with wiring layer 174 forming an electrical connection between functionality layer 73 and wiring layer 76. The “double-sloped” surface configuration resulting from the combination of insulating substrates 70, 172 and their associated electrical connection or layers 73, 174 may be incorporated into any of the other electronic package embodiments described herein. Additionally, it is contemplated that the double-sloped surface configuration may be extended to include three or more layers of insulating substrate/wiring layer stackups.

While not specifically illustrated in the drawings provided herewith, it is contemplated that an electronics package may be manufactured that includes a combination of elements of the functionality layer 73 incorporated in electronics packages 114, 138, 160, and 170. As one non-limiting example, a first portion of functional layer 73 may be formed on the backside surface 62 and/or side surface(s) 63 of semiconductor device 58 at an initial stage of the manufacturing process (or at the wafer level before singulation), similar to electronics package 114. Another portion of functional layer 73 may be formed at a later stage of manufacturing on one or more of the sloped side wall(s) 72 of insulating structure 70 and/or exposed portions of the first surface 64 of insulating substrate 66, similar to electronics packages 138 and 160.

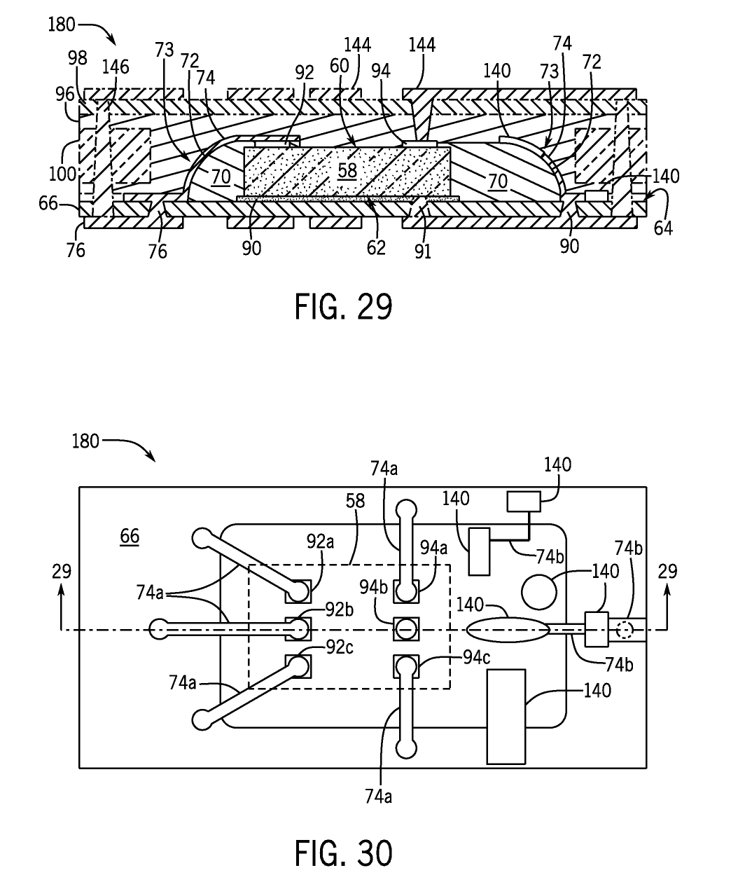

Referring now to FIGS. 29 and 30, an electronics package 180 is illustrated according to an alternative embodiment that leverages the benefits of insulating structure 70 and functionality layer 73 while positioning semiconductor device 58 in a flipped orientation as compared to previously described electronics packages 114, 138, 160, and 170. More specifically, semiconductor device 58 is positioned with its backside surface 62 coupled to the top surface 64 of insulating substrate 66, as shown in FIG. 29. Components common to electronics packages 114, 138, 160, 170, and 180 are referred to with common part numbering as appropriate.

Similar to the previously described embodiments, electronics package 180 includes an insulating structure 70 that is formed on the top surface 64 of insulating substrate 66 and surrounds at least a portion of semiconductor device 58. In the illustrated embodiment, insulating structure 70 extends over at least a portion of the active surface 60 of semiconductor device 58 in a manner that leaves contact pads 92, 94 exposed. In alternative embodiments, such as when the active surface 60 of semiconductor device 58 includes a passivation layer (not shown), insulating structure 70 may be formed to have a height less than or substantially equal to that of the semiconductor device 58 and to not coat any portion of active surface 60.

Semiconductor device 58, insulating structure 70, and functionality layer 73 are embedded within an insulating material 96. An optional core structure 100 (shown in phantom) and/or an optional second insulating substrate 98 (shown in phantom) may be included to enhance package stability.

Functionality layer 73 includes one or more electrical traces and/or communication lines 74 and one or more components 140 that are formed on the sloped side surface 72 of insulating structure 70 and/or on the top surface 64 of insulating substrate 66. One exemplary arrangement of connection lines 74 and components 140 is provided in FIG. 30, which is a top view of electronics package 180 with the insulating material 96, core structure 100, second insulating substrate 98, and wiring layer 144 omitted for clarity. As shown, some connection lines 74a form connections to contact pads 92a, 92b, 92c, 94a, and 94c of semiconductor device 58 while other connection lines 74b form electrical connections between components 140. One skilled in the art will recognize that the configuration of connection lines 74 and components 140 may be varied from that illustrated in FIG. 30 based on numerous design considerations including, for example, the particular arrangement of contact pads of the embedded electrical component(s), current carrying requirements of connection lines 74, and the type and number of components 140 included within electronics package 114.

Wiring layer 76 includes any number of penetrating contacts 90 that extend through insulating substrate 66 to electrically couple to connection lines 74. Optionally, wiring layer 76 may include one or more penetrating contacts 91 (shown in phantom) that couple to the backside surface 62 of semiconductor device 58. Wiring layer 76 also may be electrically coupled to optional wiring layer 144 through optional through connections 146 (shown in phantom). In the illustrated embodiment, wiring layer 144 extends through optional second insulating substrate 98 and insulating material 96 to electrically couple with contact pad 94. In alternative embodiments, additional contact pads may be coupled to wiring layer 144 in a similar manner. Alternatively, all electrical connections to contact pads 92, 94 may be made through connection lines 74 formed over the sloped side surface 72 of insulating structure 70.

The order and sequence the process or method steps associated with the above-described manufacturing or build-up technique for electronics packages 114, 138, and 160 may be modified from that described herein while still arriving at an equivalent or substantially equivalent end structure. As one non-limiting example, in embodiments that include second insulating substrate 98, insulating material 96 may be applied using an underfill technique after the insulating substrate 98 is incorporated within the electronics package. Additionally, some or all of vias 80, 82, 84 may be formed before semiconductor device 58 is coupled to insulating substrate 66 and the formation and patterning of the wiring layers may occur simultaneously or in the opposite order previously described herein.

In the electronics packages described herein, components 140 of functional layer 73 are formed on portions of semiconductor device 58 and/or portions of sloped side wall 72 of the insulating structure 70 and may be electrically coupled to wiring layer 76 by connection lines 74 formed on portions of sloped side wall 72. By using the sloped side wall(s) 72 and backside surface 62 of semiconductor devices 58 as contact surfaces for integral, integrated, and discrete components such as, for example, sensors, passive components, antennas, or identification tags the overall size of the electronics package can be reduced as compared to that of prior art embedded device technology.

When provided with one or more components 140 having sensor-type functionality, functional layer 73 may be configured to measure and monitor and report operating diagnostic information specific to the embedded electrical component(s) and/or other structures within the electronics package. Such functionality and monitoring may be used for preventative maintenance and obviate the need to disassemble the electronics package to obtain certain information on internal package characteristics. For example, components 140 may be configured to sense, measure, and report an operating temperature of the embedded electrical component, stress or strain conditions, or a composition of a gaseous environment in a cavity formed within the electronics package,

Beneficially, embodiments of the invention thus provide for smaller form factor compared to a prior art wire bonding package and higher thermal performance and lower costs compared to a prior art flip chip package. Embodiments of the invention disclosed herein also provide a lower cost, faster turn time process than existing prior art embedded power packages. Accordingly, the embodiments described herein provide a low cost solution with higher performance as compared to prior art approaches.

Therefore, according to one embodiment of the invention, an electronics package includes a support substrate, an electrical component having an active surface coupled to a first surface of the support substrate, and an insulating structure coupled to the first surface of the support substrate and at least one sidewall of the electrical component. A functional layer comprising at least one functional component is formed on at least one of a sloped sidewall of the insulating structure and a backside surface of the electrical component. A first wiring layer is formed on a second surface of the support substrate. The first wiring layer is electrically coupled to the functional layer through at least one via in the support substrate.

According to another embodiment of the invention, an electronics package includes a first support substrate and an electrical component having an active surface coupled to a first surface of the first support substrate, the active surface comprising at least one contact pad. An insulating structure with at least one sloped side wall is formed adjacent the electrical component and coupled to the first support substrate. The electronics package also includes a functional layer having at least one component formed on at least one of a backside surface of the electrical component and the at least one sloped sidewall of the insulating structure and at least connection line formed on the at least one sloped side wall of the insulating structure and electrically coupled to the at least one component. A first conductive layer extends through the first support substrate to couple with the at least one connection line.

According to yet another embodiment of the invention, a method of forming an electronics package includes bonding an active surface of an electronic component to a first surface of a support substrate, encapsulating at least a portion of the electronic component in a resin material, and forming a functional layer on at least one of a surface of the resin material and a backside surface of the electronic component, the functional layer comprising at least one functional component. The method also includes forming vias through the support substrate and forming a wiring layer on a second surface of the support substrate and into the vias to electrically connect to the functional layer.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

1. An electronics package comprising:
a support substrate;
an electrical component having an active surface coupled to a first surface of the support substrate;
an insulating structure coupled to the first surface of the support substrate and at least one sidewall of the electrical component;
a functional layer comprising at least one functional component formed on at least one of a sloped sidewall of the insulating structure and a backside surface of the electrical component; and
a first wiring layer formed on a second surface of the support substrate, the first wiring layer electrically coupled to the functional layer through at least one via in the support substrate.

2. The electronics package of claim 1 wherein the at least one functional component comprises one of a sensor, a passive component, an antenna, an integrated device, and an identification tag.

3. The electronics package of claim 1 wherein the active surface of the electrical component has at least one contact pad positioned thereon; and
wherein the first wiring layer extends through at least another via in the support substrate to electrically couple with the at least one contact pad.

4. The electronics package of claim 1 wherein the functional layer further comprises at least one conductive trace; and
wherein the at least one conductive trace extends over the sloped sidewall of the insulating structure and electrically couples the at least one functional component to the first wiring layer.

5. The electronics package of claim 1 wherein the functional layer further comprises at least one non-conductive communication line.

6. The electronics package of claim 1 further comprising an insulating material surrounding the electrical component, the insulating structure, and the functional layer.

7. The electronics package of claim 6 further comprising a second wiring layer electrically coupled to the first wiring layer by at least one electrical connection formed through a thickness of the electronics package; and
wherein the first wiring layer forms a first input/output connection on a first side of the electronics package and the second wiring layer forms a second input/output connection on a second side of the electronics package.

8. An electronics package comprising:
a first support substrate;
an electrical component having an active surface coupled to a first surface of the first support substrate, the active surface comprising at least one contact pad;
an insulating structure with at least one sloped side wall formed adjacent the electrical component and coupled to the first support substrate;
a functional layer comprising:
at least one component formed on at least one of a backside surface of the electrical component and the at least one sloped sidewall of the insulating structure; and
at least connection line formed on the at least one sloped side wall of the insulating structure and electrically coupled to the at least one component; and
a first conductive layer extending through the first support substrate to couple with the at least one connection line.

9. The electronics package of claim 8 wherein the at least one component comprises at least one of an integral thin film component, a discrete passive component, and an integrated component.

10. The electronics package of claim 8 wherein the at least one component comprises at least one of a passive component, a sensor component, an antenna, a MEMS component, a SAW device, and an identification tag.

11. The electronics package of claim 8 further comprising:
a second support substrate;
an insulating material located between the first and second support substrates and surrounding the insulating structure and the electrical component; and
a second conductive layer extending through the second support substrate to couple with the functional layer.

12. The electronics package of claim 8 wherein the first conductive layer further comprises:
a first portion electrically coupled to at least one contact pad of the electrical component through at least a first via formed in the first support substrate; and
a second portion electrically coupled to the functional layer through at least a second via formed in the first support substrate.

13. The electronics package of claim 8 wherein the functional layer comprises:
at least a first component and a second component; and
at least one connection line electrically coupling the first component to the second component.

14. The electronics package of claim 8 wherein a first portion of the functional layer is formed on the first surface of the first support structure;
wherein a second portion of the functional layer is formed on the backside surface of the electrical component; and
wherein a third portion of the functional layer is formed on the insulating structure.

15. A method of forming an electronics package comprising;
bonding an active surface of an electronic component to a first surface of a support substrate;
encapsulating at least a portion of the electronic component in a resin material;
forming a functional layer on at least one of a surface of the resin material and a backside surface of the electronic component, the functional layer comprising at least one functional component; and
forming a wiring layer on a second surface of the support substrate, the wiring layer electrically connected to the functional layer through at least one via in the support substrate.

16. The method of claim 15 wherein forming the functional layer comprises forming one of a sensor, a passive component, an antenna, an integrated device, and an identification tag.

17. The method of claim 15 further comprising forming the wiring layer to extend through at least another via in the support substrate to electrically couple with at least one contact pad located on the active surface of the electronic component.

18. The method of claim 15 wherein forming the functional layer further comprises forming at least one conductor on a surface of the resin material, the at least one conductor electrically coupling the at least one functional component to the wiring layer.

19. The method of claim 15 further comprising surrounding the electrical component, the resin material, and the functional layer in an insulating material.

20. The method of claim 15 further comprising forming a second wiring layer on the outer surface of the resin material, the second wiring layer coupled to the wiring layer by at least one electrical connection formed through a thickness of the electronics package.

21. The method of claim 15 further comprising bonding the electronic component to the support substrate with a resin material disposed on one of a surface of the electronic component and the first surface of the support substrate.

22. The method of claim 15 further comprising forming the functional layer by one or more of direct dispense, subtractive processing, semi-additive processing, and component placement.

23. The method of claim 15 wherein the forming vias through the support substrate comprises one or more of laser drilling, mechanical drilling, plasma etching, and chemical etching.

24. The method of claim 15 comprising forming the wiring layer on the second surface of the support substrate and into the vias by depositing and patterning a metal layer by one or more of sputtering, evaporation, electroless plating, and electro-plating.

25. The method of claim 15 further comprising forming a conductor on the second surface of the electronic component.

26. The method of claim 15 wherein encapsulating at least a portion of the electronic component in the resin material further comprises disposing a resin material around the electronic component and curing the resin material.

27. The method of claim 15 further comprising mounting a support structure on the first surface of the support substrate, the support substrate having an opening sized to accommodate the electronic component.
